(19) United States
(12) Patent Application Publication
(10) Pub. No.: US 2006/0186937 A1
(43) Pub. Date: Aug. 24, 2006

(54) Active noise regulator

(76) Inventor: Rajendran Nair, Gilbert, AZ (US)

Correspondence Address: Rajendran Nair;ComLSI Inc., 3838 E. Encinas Ave., Gilbert, AZ, 85234, US

(21) Appl. No.: 11/063,304

(22) Filed: Feb. 22, 2005

(51) Int. Cl. H03K 3/356

(52) U.S. Cl. 327/210; 327/391; 327/437

(57) ABSTRACT

The invention proposes noise suppression circuits mounted on the package of a high power, high frequency ULSI component. In this architecture, termed an active noise regulator (ANR), charge is stored on dedicated reservoir capacitors at a voltage substantially higher than the operating voltage of the ULSI device. These reservoir capacitors are mounted upon active circuits packaged to match the size and form factor of the capacitors and this assembly is then attached to the package substrate. Charge is conveyed from the reservoir capacitors to the ULSI power grid when there is a sudden load current demand in the ULSI device. The capacitors are depleted by the flow of charge through inductances in the discharge pathway. The capacitors are then recharged either by the overshoot that results from a sudden release of the ULSI load current demand or by a gated charging pathway connected to a high voltage supply. The use of the depleted reservoir capacitor to absorb power grid voltage overshoots assists in maintaining power integrity for the ULSI device while conserving energy in the power pathways. The circuits within the active device may be any combination of semiconductor switches and/or voltage regulators, and may also contain voltage and current sensing circuitry.

### CROSS-REFERENCE TO RELATED DOCUMENTATION

This application relates to U.S. Utility patent application Ser. No. 10/875,022 dated the 24^{th} of Jun. 2004, entitled “Voltage Droop Suppressing Active Interposer” and to U.S. Utility patent application Ser. No. 10/766,270 dated the 29^{th} of Jan. 2004, entitled “Method & apparatus for transient suppressing high-bandwidth voltage regulation”.

### TECHNICAL FIELD OF THE INVENTION

Embodiments of the invention relate to electronic circuitry commonly employed to provide regulated voltages to other electronic, electro-mechanical or electro-optic devices and systems. Such circuitry falls under the broad category of power delivery management electronics.

### BACKGROUND & PRIOR ART

Greater levels of integration of transistors devices in ULSI chips, a consequence of device size scaling, leads to greater power consumption despite the reduction in operating voltages. This leads to increasing operating currents, and consequently an increased need for stored charge in close proximity to devices in the nanoscale regime integrating 100's of millions of transistor devices. While capacitor technology continues to scale, providing increased capacitance values within the same or smaller form factors, the noise created by state-transitions of high-performance, high-power components, referred to as voltage droops and overshoots, requires alternate, active techniques that improve the effectivity of stored charge in quenching noise.

Active devices have been proposed in the art to minimize high-frequency power grid noise that the voltage regulation modules of the system are unable to respond to. These are described in detail in U.S. application Ser. Nos. 10/875,022 and 10/766,270. While these active devices assist in voltage droop suppression as shown in FIG. 1, they are subject to some limitations:
These active devices, while minimizing voltage droop, may give rise to increased voltage overshoot upon sudden reduction of load current demand
These active devices trade power for noise; they consume additional energy in the noise reduction function that impacts overall power system efficiency.

These disadvantages diminish the beneficial impact of such active circuits employed for noise reduction. A need therefore exists for improvement upon their noise suppression architecture.

### INVENTION SUMMARY

Prior art droop suppression circuits employ a reservoir capacitor charged to a higher potential than the load in order to provide an inrush of needed charge. The invention proposes a gated charge and gated discharge path for the reservoir capacitor. This allows for the depletion of most of the charge in the reservoir capacitor in response to a sudden load demand through the disconnection of the charging pathway and conduction through the discharge pathway. Discharge of the reservoir capacitor to ground potential or negative potentials is enabled by the energy developed in the discharge pathway inductances. During this process, the gated charge pathway remains disconnected. After the reservoir capacitor reaches the required (near zero or negative) potential, it is now capable of absorbing any voltage overshoot that results on the power grid of the load because of the load demand suddenly ceasing or reducing substantially. The inductive energy stored in the primary power pathway to the load from the voltage regulation modules, that would ordinarily cause a voltage overshoot, is instead recovered through a reconnection of the depleted ANR reservoir capacitor to the power grid when the load demand turns off or drops. The improved ANR therefore serves an energy recovery function while assisting in minimizing noise on the power grid at the load. Working symbiotically with the load device in maintaining load power integrity, one or more ANR's enable fast turn-on and turn-off of high-power loads.

### BRIEF DESCRIPTION OF THE FIGURES

FIG. 1 illustrates prior art voltage droop suppression function in simulation waveforms.

FIG. 2 is an illustration of prior art assembly of active droop suppressors on a VLSI package.

FIG. 3 is an illustrative circuit diagram of a patent pending prior art ANR embodiment.

FIG. 4 illustrates an architectural embodiment of the invention

### DETAILED DESCRIPTION

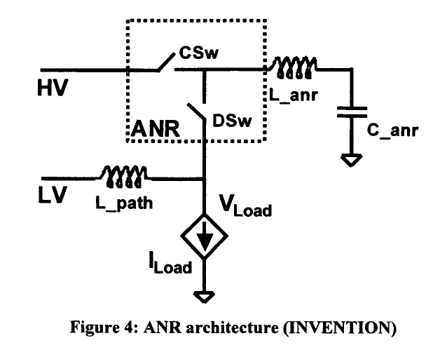

FIG. 4 illustrates an embodiment of the invention architecture. The two switches enclosed within the dashed-line box represent the active noise regulator (ANR) component. L_anr and C_anr represent the parasitic loop inductance and the capacitance of the reservoir capacitor attached to the ANR. CSw is the charging path switch and DSw is the discharge path switch device within the ANR. L_path is the path inductance from the voltage regulation modules that form the primary power supply to the load ULSI component which is represented by I_load. HV is the higher voltage provided to the ANR component and LV is the voltage provided by the voltage regulation module to the load ULSI component. V_load is the voltage at the power grid of the ULSI component.

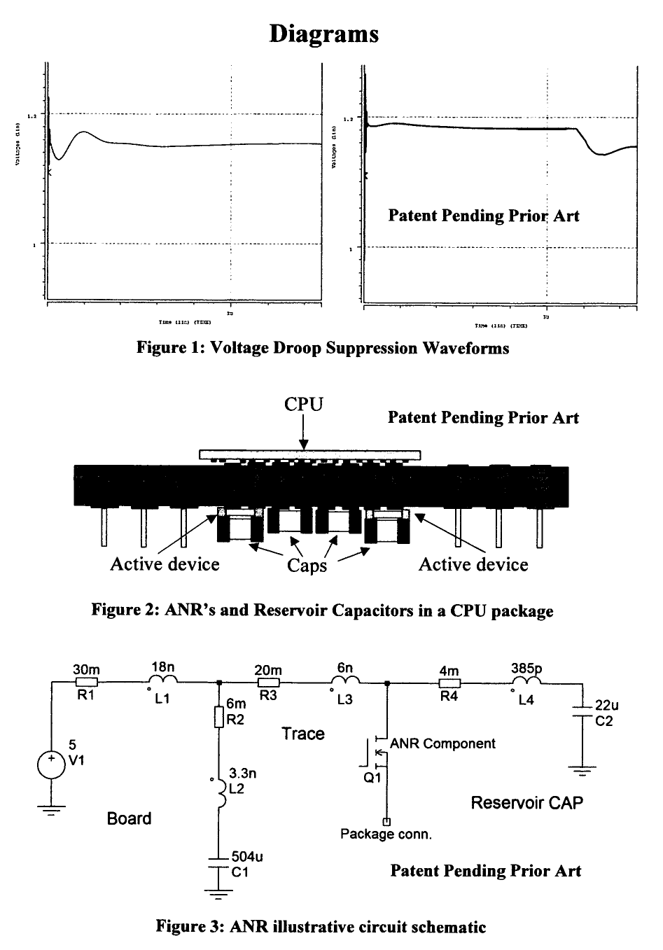

FIG. 1 shows simulation viewgraphs for a prior art voltage droop suppression component. The graph on the left of the figure corresponds to a plot of voltage with time on a power grid disturbed by a high-current, sudden load demand. The graph on the right corresponds to the same system with the inclusion of active droop suppression functionality. One skilled in the art can see that the ripples in the power supply that constitute a degradation of power integrity are substantially minimized immediately after the transient load event occurs. When active droop suppression functionality is terminated, the voltage, nominally expected to be 1.2V, falls back to the behavior seen in the graph on the left.

FIG. 2 illustrates a preferred placement of droop suppression components close to a high-performance, high-power load. The adjacency of the active component to the load component assists in minimizing the electrical impedance as well as the thermal resistance between them. This assists in rapid charge transfer from the reservoir capacitor into the load power grid, and in cooling the active noise suppression component by sharing the cooling resources ordinarily associated with the load component.

FIG. 3 provides a circuit schematic that illustrates voltage droop suppression function. Voltage droop suppression is accomplished by the transfer of charge from a reservoir storing charge at a higher voltage into the load through the ANR component. This charge transfer is initiated during a load ‘transient’ event, or a change in its power consumption state that produces a significant change in its electric current draw.

With reference to FIG. 4, by providing an isolation switch between the HV input and the reservoir capacitor, the invention permits a change in charge in the reservoir capacitor C_anr from positive to negative polarity with respect to ground. This change in charge allows C-anr to absorb voltage overshoots that come about on the V_load node. Therefore device DSw conducts bi-directionally in the invention as opposed to the prior art. The sequence of events that permit the absorption of overshoot in the invention are as follows:
1. At system power-up, the reservoir capacitor charges up to HV through switch CSw of the ANR component. Switch DSw is open.
2. During a transient ‘positive’ load event, where the load component displays a sudden increase in its load current, switch CSw is opened.
3. Switch DSw is closed, discharging C_anr into V_Load.
4. Current ramps up rapidly through L_anr, reaching a peak value through the ANR.
5. The energy stored in L_anr enables a current flow to continue while the voltage at C_anr falls below V_Load.
6. Switch DSw is opened when the charge in C_anr is changed by a pre-determined extent
7. The ANR waits for indications of an overshoot event.
8. When an overshoot event is indicated and detected, the ANR closes switch DSw again, discharging the excess charge on V_Load into C_anr.
9. At a pre-determined transition point, switch CSw is closed and switch DSw is opened.
10. C_anr continues charging to HV through switch CSw & the ANR prepares for another load positive transient event.

As long as HV is greater than twice the value of LV, the reservoir capacitor can discharge down to zero potential across its plates or reverse the charge contained in it. This action is facilitated by inductance present or designed into the charge flow path. Switch DSw enables an oscillatory (or resonant) transfer of charge in a manner akin to the function of a tank circuit, albeit with a delay and the involvement of external energy storage elements. Depending upon the design and fabrication of the ANR component, the reservoir capacitor voltage may be discharged to a substantially negative potential with respect to the system ground, allowing the possibility of a recharge of the reservoir capacitor to the HV level through the overshoot absorption action. This could greatly improve the efficiency of the noise reduction function through a minimization of the external energy supplied to the ANR component.

The reverse flow of charge back into the reservoir capacitor from V_Load is facilitated by two factors:
1. The discharge of C_anr below V_Load to a near-zero or negative voltage, and
2. The inductive energy present in L_path, the inductance in the primary pathway for power into the ULSI load component continues the flow of current despite the reduction in current demand at the load.

Reverse charge flow is initiated during the overshoot event through L_anr into C_anr. This flow of charge also peaks in current flow and continues to charge C_anr to a voltage above V_Load until the energy in L_anr is dissipated. In this fashion, ANR's act as shock absorbers minimizing the impact of droops and overshoots on ULSI component performance.

The ANR component may be designed in any semiconductor fabrication process that provides devices exhibiting controlled switch action. Due to high currents flowing through the component, care must be taken to ensure that heat is extracted away from the component through component packaging and assembly as in the referenced prior art [1, 2]. Techniques as employed in the referenced prior art [1, 2] also need to be employed to ensure that the switches display the least amount of ‘ON Resistance’ such that the energy dissipated in the component is kept low. Due to the bidirectional nature of the current flow in switch DSw, it is also important that a bilaterally symmetric switch device, such as a MOSFET, be used in the ANR component to realize that function.

Although specific embodiments are illustrated and described herein, any circuit arrangement configured to achieve the same purposes and advantages may be substituted in place of the specific embodiments disclosed. This disclosure is intended to cover any and all adaptations or variations of the embodiments of the invention provided herein. All the descriptions provided in the specification have been made in an illustrative sense and should in no manner be interpreted in any restrictive sense. The scope, of various embodiments of the invention whether described or not, includes any other applications in which the structures, concepts and methods of the invention may be applied. The scope of the various embodiments of the invention should therefore be determined with reference to the appended claims, along with the full range of equivalents to which such claims are entitled. Similarly, the abstract of this disclosure, provided in compliance with 37 CFR §1.72(b), is submitted with the understanding that it will not be interpreted to be limiting the scope or meaning of the claims made herein. While various concepts and methods of the invention are grouped together into a single ‘best-mode’ implementation in the detailed description, it should be appreciated that inventive subject matter lies in less than all features of any disclosed embodiment, and as the claims incorporated herein indicate, each claim is to viewed as standing on it's own as a preferred embodiment of the invention.

### REFERENCES

1. Nair, U.S. utility application Ser. No. 10/766,270, “Method and apparatus for transient suppressing high bandwidth voltage regulation”, filing date: Jan. 29, 2004
2. Nair, U.S. utility application Ser. No. 10/875,022, “Voltage droop suppressing active interposer”, filing date Jun. 24, 2004
3. Nair, et al., USPTO publication number 20030081389, “Silicon interposer-based hybrid voltage regulator system for VLSI devices”, filed: Oct. 26, 2001
4. Liao, U.S. Pat. No. 6,853,565, “Voltage overshoot reduction circuits”, filed May 23, 2003
5. Muhtaroglu, et al., U.S. Pat. No. 6,747,470, “Method and apparatus for on-die voltage fluctuation detection”, filed Dec. 19, 2001
6. Barnes, et al., U.S. Pat. No. 6,677,736, “Energy recovery system for droop compensation circuitry”, filed Sep. 28, 2001
7. Kumar, et al., U.S. Pat. No. 6,611,435, “Voltage regulator with voltage droop compensation”, filed Jan. 8, 2002

What is claimed is:

1. An electronic circuit apparatus, comprising:
A first electronic switch device, a second electronic switch device and a reservoir capacitor, where an electronic switch device is a controllable conduction path for electric charges;
A first input circuit node, connecting to a first conduction terminal of the first electronic switch;
A second output circuit node, connecting to a first conduction terminal of the second switch;
A common node forming the junction of the second conduction terminal of the first switch, the second conduction terminal of the second switch and the first plate terminal of the reservoir capacitor;
And a power supply reference node connecting to the second plate terminal of the reservoir capacitor.

2. The apparatus of claim 1 where the first electronic switch, the second electronic switch, and their control circuits are fabricated on a monolithic semiconductor substrate.

3. The apparatus of claim 1 where the first electronic switch, the second electronic switch, their control circuits and an integrated capacitor connecting with one plate terminal to the common junction node and its other plate terminal to a power supply reference node are fabricated on a monolithic semiconductor substrate.

4. The apparatus of claim 1 where the absolute value of the voltage at the first input node is greater than the absolute value of the voltage at the second output node.

5. The apparatus of claim 1 where the first switch, the second switch, the reservoir capacitor and an inductor in the charge conduction path through the second switch are fabricated on a monolithic semiconductor substrate.

6. The apparatus of claim 1 where the first switch, the second switch and their control circuits are integrated with noise detection circuits that receive a signal indicating a power state change event from the load component connecting to the second output node.

7. The apparatus of claim 1 attached directly opposite to the ULSI load component on a package substrate such that the physical distance between the load component and the invention apparatus is approximately the thickness of the CPU package substrate.

8. The apparatus of claim 1 where the first switch, the second switch, control and detection circuits and other related devices are fabricated on an integrated circuit chip that is packaged to match the electrical and mechanical form factor of the reservoir capacitor such that the reservoir capacitor mates electrically and mechanically to the integrated circuit chip on one of its packaged surfaces, and this assembly attaches by the other surface of the integrated circuit chip to the load component's package substrate.

9. The apparatus of claim 1 where the first electronic switch, the second electronic switch and their associated detection and control circuits are integrated monolithically and fabricated in a complementary-metal-oxide-semiconductor (CMOS) fabrication process.

10. The apparatus of claim 1 employed to suppress voltage droops and overshoots on a power supply node or grid.

11. The apparatus of claim 1 employed to convert an input DC voltage to an output DC voltage provided to the load component.

12. One or more of the apparatus of claim 1, receiving a signal or multiple signals from the load component, employed to reduce power state transition induced noise on the load component's power grid node.

13. A method for noise suppression and energy recovery, comprising:
The flow of charges gated by an electronic switch from a capacitor through an inductor into a power node of a load component requiring high current flow, said flow of charges induced by a driving potential difference between the voltage on the capacitor and the voltage at the power node;
The continuation of this flow of charge from the capacitor into the power node after the said driving potential difference has reduced to near zero or beyond, such continued flow being driven by the magnetic energy stored in the inductor in series with the capacitor in the charge flow path;
The disconnection of the gating switch when said charge flow diminishes and/or attempts to change direction, or when the capacitor reaches a predetermined voltage condition;
A reconnection of the gating switch, allowing charge flow in the reverse direction from the power node into the capacitor when an opposite change in the current demand at the load component induces the voltage on the power node to change, such change being brought about by the magnetic energy developed and stored in the inductance inherent in the primary power pathway to the load component;
A disconnection of the gating switch when the charge flow diminishes and/or attempts to change direction, and continued charging of the capacitor through a separate charging path to bring it back to its initial charged state.

14. The method of claim 13 employed to diminish voltage droops and subsequent voltage overshoots on a load component power grid, where the load component may be microprocessors, graphics coprocessors or other ULSI components.

15. The method of claim 13 employed to recover and use energy developed and stored in the inductance elements inherent in power pathways to load components and in associated power integrity management components such as capacitors.

16. A method for active noise regulation, comprising:
Signal communication from a load component to an electronic circuit indicating the onset of a power state change inducing noise on the component power grid;
And controlled flow of electric charge, from a capacitor storing charge at a potential different from that of the load component power node, through an electronic switch of the said electronic circuit into the component power grid to suppress or diminish such noise.

17. The method of claim 16, where the said electronic circuit comprises of circuit elements integrated monolithically, co-packaged with a discrete capacitor, mounted at close proximity to the circuits of the load component.

18. Electronic systems comprised of various integrated and discrete electronic circuits and devices, electro-chemical, electro-thermal, electro-mechanical and electro-optic devices that employ the method of claim 16 in any embodiment.

19. Electronic systems comprised of various integrated and discrete electronic circuits and devices, electro-chemical, electro-thermal, electro-mechanical and electro-optic devices that employ the apparatus of claim 1 in any embodiment.

20. Electronic systems comprised of various integrated and discrete electronic circuits and devices, electro-chemical, electro-thermal, electro-mechanical and electro-optic devices that employ the method of claim 13 in any embodiment.
